(19) United States
(12) Patent Application Publication
(10) Pub. No.: US 2011/0147845 A1
(43) Pub. Date: Jun. 23, 2011

(54) Remote Doped High Performance Transistor Having Improved Subthreshold Characteristics

(76) Inventors: Prashant Majhi, Austin, TX (US); Kausik Majumdar, Bangalore (IN)

(21) Appl. No.: 12/644,657

(22) Filed: Dec. 22, 2009

(51) Int. Cl. H01L 29/78; H01L 21/336; H01L 23/48

(52) U.S. Cl. 257/368; 438/526; 257/690; 438/282; 257/402; 257/E29.264; 257/E23.01; 257/E21.409; 257/E21.135

(57) ABSTRACT

Devices comprising, and a method for fabricating, a remote doped high performance transistor having improved subthreshold characteristics are disclosed. In one embodiment a field-effect transistor includes a channel layer configured to convey between from a source portion and a drain portion of the transistor when the transistor is in an active state. Further, the field-effect transistor includes a barrier layer adjacent to the channel layer. The barrier layer comprises a delta doped layer configured to provide carriers to the channel layer of the transistor, while preferably substantially retaining dopants in said delta-doped layer.

### TECHNICAL FIELD

This invention relates to semiconductor devices and more particularly relates to an apparatus system and method providing for a remote doped field effect transistor.

### BACKGROUND OF THE INVENTION

In the field of semiconductor device fabrication, progress is usually gauged by a reduction in the size of semiconductor components. Unfortunately, certain semiconductor structures and materials may become unsuitable as the size decreases. More specifically in transistor design, with the reduction of channel length it is more difficult to control short channel effects. The controlling of such effects becomes even more important in high mobility channel materials due to their low band gap and poor short channel characteristics.

One solution to assist in controlling short channel effects in high mobility devices is to heavily dope the channel. However, such doping eventually increases scattering, which leads to lower mobility and, thus, frustrates the main advantage of high mobility channel materials. Doped channels also come with other drawbacks such as variability which arises due to the number and position fluctuations of dopants.

The referenced shortcomings are not intended to be exhaustive, but rather are among many that tend to impair the effectiveness of previously known techniques and devices; however, those mentioned here are sufficient to demonstrate that the methodologies appearing in the art have not been satisfactory and that a significant need exists for the techniques described and claimed in this disclosure.

### SUMMARY OF THE INVENTION

The present disclosure provides for an apparatus, system, and method which enables the advantages of both the high mobility of undoped channels, and the better short channel characteristics of doped channels by the use of a remote doped layer. In one embodiment, a Field-Effect Transistor (FET) is provided which includes a channel layer configured to convey charge between a source portion and a drain portion of the FET, when the FET is in an active state. Further, the FET may include a barrier layer adjacent to the channel layer. The barrier layer may comprise a delta doped layer configured to carriers to the channel layer, while substantially retaining dopants in said delta-doped layer. The delta doped layer provides minority carriers to the channel (holes for NMOS and electrons for PMOS) to improve short channel characteristics of the transistor. The presence of the delta doped layer will assist in controlling the threshold voltage of a transistor device in the absence of channel dopants, and will thus improve the subthreshold characteristics of the device. Such doping may also reduce underlap length of a transistor device.

In more detailed embodiments, the barrier layer may include either a p-type or n-type delta doped layer which will provide holes or electrons, respectively, to the channel layer of the transistor. The delta doped layer may be located within the barrier layer such that the distance between the delta doped layer and the channel layer is approximately 2 nm. Some embodiments may be fabricated with materials such as group III-V or group IV materials. Further, certain embodiments may include transistors that are multigate (e.g. FinFET, Tri-gate, etc.) devices, or single gate Metal-oxide Semiconductor Field-Effect Transistor (MOSFET) devices.

An Integrated Circuit (IC) device is also disclosed. In one described embodiment, the IC device includes a chip package configured to house an IC, multiple electrical interface pins configured to conduct electrical signals, and an IC that includes at least one FET device disposed within the chip package. The FET may include a channel layer configured to convey charge between a source portion and a drain portion of the FET, when the FET is in an active state. The FET may further include a barrier layer adjacent to the channel layer. The barrier layer may include a delta doped layer configured to provide carriers to the channel layer, while substantially retaining dopants in said delta-doped layer.

A method for fabricating an FET is also described. The method in the disclosed embodiments substantially includes the steps necessary to carry out the functions presented with respect to the embodiments discussed above. In one embodiment, the method includes providing a channel layer configured to convey charge between a source portion and a drain portion of the FET when said transistor is in an active state. The method further includes providing a barrier layer adjacent to the channel layer and forming a delta doped layer within the barrier layer. The delta doped layer may be configured to provide holes or electrons to the channel layer of the FET.

The terms “a” and “an” are defined as one or more unless this disclosure explicitly requires otherwise.

The term “substantially” and its variations are defined as being largely but not necessarily wholly what is specified as understood by one of ordinary skill in the art, and in one non-limiting embodiment “substantially” refers to ranges within 15%, preferably within 10%, more preferably within 5%, and most preferably within 1% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1 is a schematic cross section diagram illustrating one embodiment of a FET device;

FIG. 2 is a schematic cross section diagram illustrating an alternate embodiment of a FET device;

FIG. 3A-3B are band diagrams in accordance with embodiments of the present invention;

FIG. 4A-4B are source to channel to drain band diagrams in accordance with embodiments of the present invention;

FIG. 5 is a schematic top view and detailed view illustrating one embodiment of an IC device in accordance with embodiments of the present invention; and

FIG. 6 is a schematic flow chart diagram illustrating one embodiment of a method for fabricating a FET device.

### DETAILED DESCRIPTION

Various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

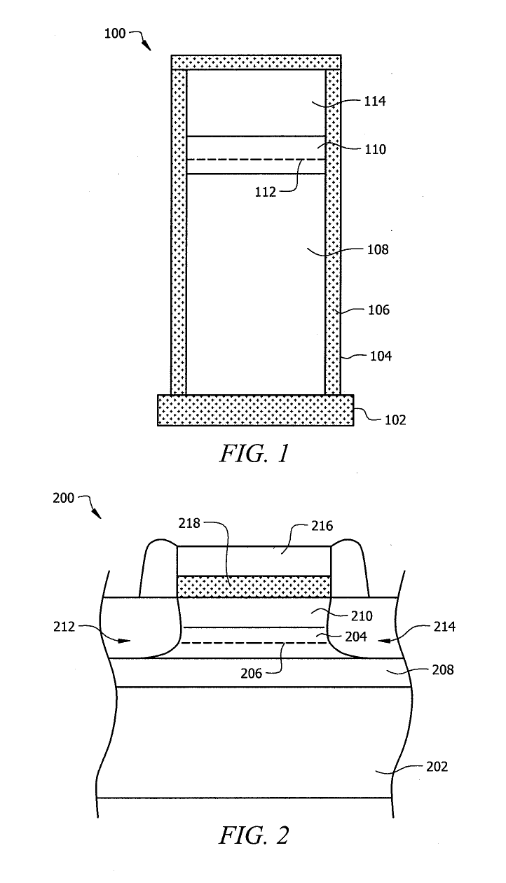

FIG. 1 illustrates one embodiment of a remote doped high performance transistor 100. Transistor 100 may include a buried oxide layer (BOX) 102, gate portion 104, and gate insulator portion 106. Channel layer 108 is configured to convey charge between the source and drain portion of transistor 100 when transistor 100 is in an active state. An active state may include any state whereby the transistor is meant to conduct charge, (e.g., depletion mode, enhancement mode, etc.). Channel layer 108 is preferably undoped, however some embodiments may utilize a mildly to heavily doped channel to suit various preferences.

Barrier layer 110 may be provided adjacent to channel layer 108. Barrier layer 110 may include a delta doped layer 112 configured to provide carriers to channel layer 108, while substantially retaining dopants in delta-doped layer 112. Delta doped layer 112 provides minority carriers to the channel (holes for NMOS and electrons for PMOS) to improve short channel characteristics of the transistor. Delta doped layer 112 may comprise a p-type delta doped layer which is configured to provide holes to channel layer 108 when transistor 100 is in an active state. Moreover, delta doped layer 112 may comprise an n-type delta doped layer which is configured to provide electrons to channel layer 108 of transistor 100. The doping of delta doped layer may be accomplished by any method including in-situ doping and the like.

In some embodiments, delta doped layer 112 is located approximately 2 nm within barrier layer 110 and away from channel layer 108. This spacing allows for the efficient donation of holes or electrons while also substantially spacing the dopants of delta doped layer 112 from channel layer 108.

Transistor 100 may be a multigate device such as a Tri-gate or a FinFET device. Such devices could utilize barrier layer 110 and delta doped layer 112 as described herein in accordance to their respective designs. Transistor 100 is illustrated as a FinFET device and may include hard mask layer 114 placed above barrier layer 110. Hard mask layer 114 may function to provide dielectric insulation between the upper part of gate portion 104, and both barrier layer 110 and channel portion 108.

FIG. 2 illustrates another embodiment of a remote doped high performance transistor 200. Transistor 200, as shown in FIG. 2, may be embodied as a planar MOSFET and may include a substrate layer 202. Barrier layer 204 may be similar in structure and in function as discussed with respect to barrier layer 110. Barrier layer 204 may also include remote doped layer 206 which may be similar in structure and in function as discussed with respect to remote doped layer 112.

Transistor 200 may include a second barrier layer 208 which may function to provide lattice match and lower leakage. Barrier layer 204 may be placed between second barrier layer 208 and channel layer 210 such that remote doped layer 206 may provide carriers to channel layer 210 when charge is moving between source portion 212 and drain portion 214. Transistor 200 may include gate portion 216, and embodiments may also include gate insulator 218, source spacer 220, and drain spacer 222, configured to compensate for electrostatic and other non-desirable effects.

Embodiments may be fabricated using any materials suitable for the desired functionality. For example, embodiments may be fabricated using group 111-V materials (examples of such materials are listed in table 1 below).

TABLE 1

Example III-V semiconductors
Aluminum antimonide (AlSb)
Aluminum arsenide (AlAs)
Aluminum nitride (AlN)
Aluminum phosphide (AlP)
Boron nitride (BN)
Boron phosphide (BP)
Boron arsenide (BAs)
Gallium antimonide (GaSb)
Gallium arsenide (GaAs)
Gallium nitride (GaN)
Gallium phosphide (GaP)
Indium antimonide (InSb)
Indium arsenide (InAs)
Indium nitride (InN)
Indium phosphide (InP)
III-V ternary semiconductor alloys
Aluminum gallium arsenide (AlGaAs, AlₓGa₁₋ₓAs)
Indium gallium arsenide (InGaAs, InₓGa₁₋ₓAs)
Indium gallium phosphide (InGaP)
Aluminum indium arsenide (AlInAs)
Aluminum indium antimonide (AlInSb)
Gallium arsenide nitride (GaAsN)
Gallium arsenide phosphide (GaAsP)
Aluminum gallium nitride (AlGaN)
Aluminum gallium phosphide (AlGaP)
Indium gallium nitride (InGaN)
Indium arsenide antimonide (InAsSb)
Indium gallium antimonide (InGaSb)
III-V quaternary semiconductor alloys
Aluminum gallium indium phosphide
(A1GaInP, also InAlGaP, InGaAlP, AlInGaP)
Aluminum gallium arsenide phosphide (AlGaAsP)
Indium gallium arsenide phosphide (InGaAsP)
Aluminum indium arsenide phosphide (AlInAsP)
Aluminum gallium arsenide nitride (AlGaAsN)
Indium gallium arsenide nitride (InGaAsN)
Indium aluminum arsenide nitride (InAlAsN)
Gallium arsenide antimonide nitride (GaAsSbN)
III-V quinary semiconductor alloys

Gallium indium nitride arsenide antimonide (GaInNAsSb)
Gallium indium arsenide antimonide phosphide (GaInAsSbP)

For example, some embodiments may utilize InAs or InGaAs materials for the channel portions 108 210; AlSb or AlAs materials for barrier layer portions 110 204, with delta doped layers 112 206 being created by introducing a thin area of dopants into the barrier layer portion; and hard mask layer 114, second barrier layer 208, gates 104 216, and gate insulators 104 218 may be fabricated using any suitable material to accomplish the respective design parameters of such portions. It is noted that preferable materials for barrier layers and delta doped layers will vary depending the materials utilized for the channel portion. Suitable barrier layers will result in a wider band gap than the channel portion so as to better provide carriers to the channel.

The use of these types of materials in the manner discussed above offers several advantages over currently fabricated silicon-based transistors. For example, they will allow for better performance, while requiring lower power. These advantages will be particularly helpful for future miniaturization endeavors.

Still further, embodiments may be fabricated using group IV materials (e.g. silicon, germanium, and the like). Such materials may be selected in accordance to design goals and other considerations taken into account by those of skill in the art.

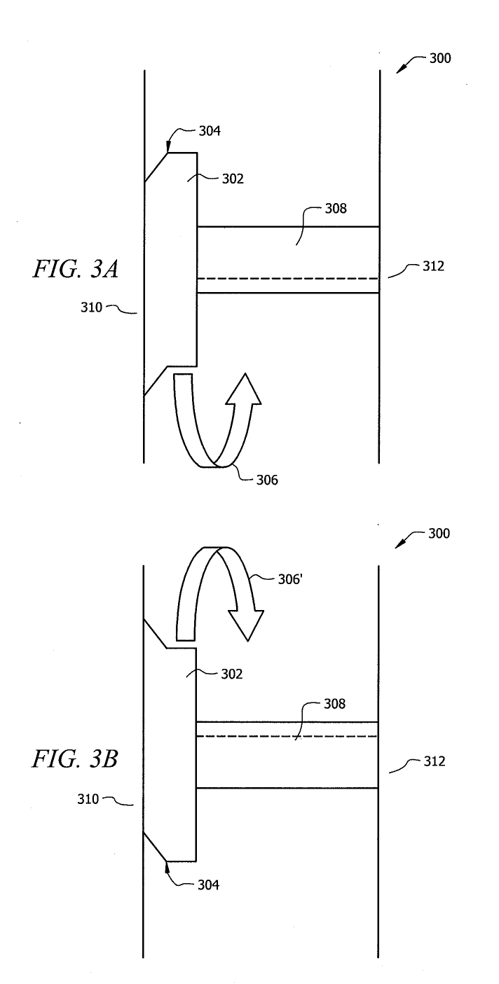

FIGS. 3A and 3B illustrate a band diagram 300 corresponding to embodiments such as those described with respect to FIGS. 1 and 2. Barrier layer 302 includes delta doping plane 304, which, when active, allows holes 306 or electrons 306′ to spill over into channel 308. Region 310 may illustrate hard mask portion 108 or second barrier layer 208, while region 312 may illustrate BOX 102 or gate insulator 218. FIG. 3A illustrates an n-type device where delta doping plane 304 includes p-type doped material providing holes 306 to channel 308, whereas FIG. 3B illustrates a p-type device where delta doping plane 304 includes an n-type delta doped material providing electrons 306′ to channel 308.

As shown in FIGS. 3A and 3B, embodiments of the present disclosure create a wide band gap between barrier layer 302 and channel 308. This layout facilitates the movement of holes 306 and electrons 306′ into the channel 308 of the transistor. The described architecture further separates dopants from the channel, which provides improved performance when the transistor is in an inactive state.

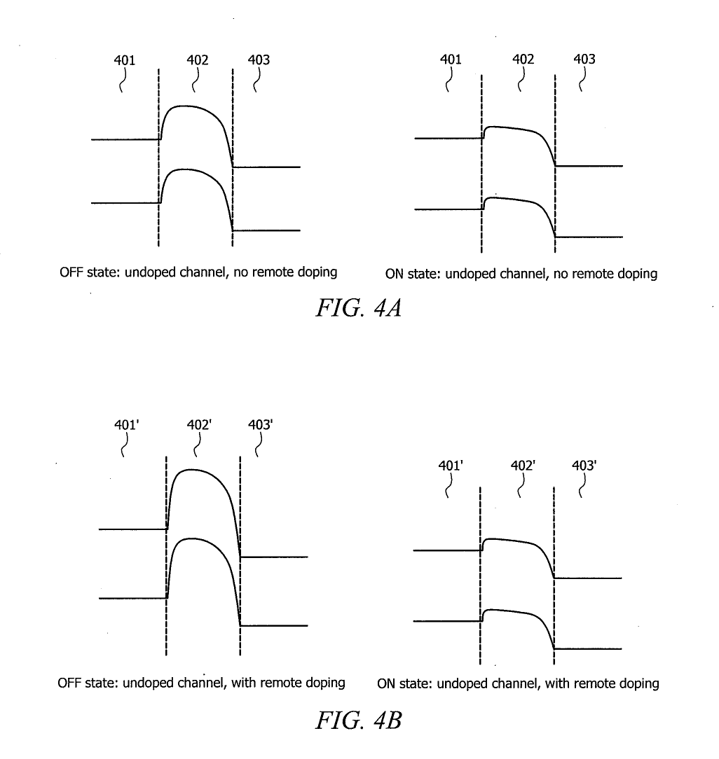

FIGS. 4A and 4B illustrate source to channel to drain band diagrams corresponding to embodiments of the present disclosure. FIG. 4A illustrates the off and on states of a transistor having an undoped channel and no remote delta doped layer, whereas FIG. 4B illustrates the off and on states of a transistor having an undoped channel and a remote delta doped layer. These figures are characterized by source region 401 401′, channel region 402 402′, and drain region 403 403′. As can be seen, implementation of a delta doped layer as described herein greatly increases the off-state reliability of a transistor and allows for better control short channel effects.

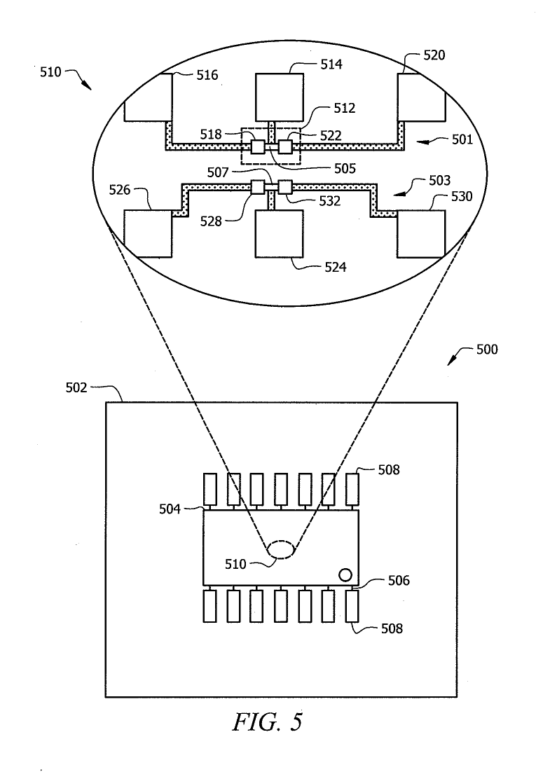

FIG. 5 illustrates one embodiment of an IC device 500. In the depicted embodiment, the IC device may include an integrated chip component. The chip may include a chip package 504, an IC 510, and one or more electrical interface pins 508. For simplicity these component may be referred to collectively as “chip 504.” A portion of the IC 510 is described in further detail. In the detailed illustration, the IC 510 may include, among other things, one or more FETs 100 200. Various embodiments of FETs 100 200 are described above. In this depicted embodiment, the IC 510 includes a PFET transistor 501 and an NFET transistor 503. In a further embodiment, these transistors may be coupled to form a complimentary transistor pair.

The depicted PFET transistor 501 includes a channel with an adjacent barrier layer having an n-type delta doped portion. Region 518 and region 522 may be p-typed doped. Therefore, regions 518 and 522 may be separated by an n-type region 512. In addition, the PFET transistor may include a gate electrode 505. Region 518 may be coupled to source terminal or connection pad 516, region 522 may be coupled to drain pad 520, and gate electrode 505 may be connected to gate pad 514.

Similarly, NFET transistor 503 includes a channel with an adjacent barrier layer having an p-type delta doped portion. NFET transistor 503 further includes regions 528 and 532 which may be n-type doped, and gate electrode 507. Region 528 may be coupled to source terminal or connection pad 526, region 532 may be coupled to drain pad 530, and gate electrode 507 may be connected to gate pad 524.

In various other embodiments of the IC, the transistors may be coupled directly to other transistors, or IC components through metal layers or connections. Indeed, certain ICs may include multiple layers, wherein the transistors are connected through vias between the layers. The IC may comprise a memory device, a processing device, a Radio Frequency (RF) device, a control device, a Field Programmable Gate Array (FPGA), an Application Specific Integrated Circuit (ASIC), a Programmable Logic Device (PLD), or the like. Although several embodiments of a chip 304 have been listed for illustrative purposes, one of ordinary skill in the art will recognize that this is not an exhaustive list of possible IC devices 500.

In a further embodiment, the chip 504 may be coupled to a circuit card 502 using one or more contact pads 508 or other means for electrical communication. For example, a computer motherboard may include a plurality of chips 504 containing ICs 510. In one embodiment, the chip 504 may be a computer processor, or the like. Alternatively, certain wireless communication devices may include wireless cards 502 which may include one or more chips 504 in a set of communication chips 504. Such chips 504 may include ICs 510 that contain one or more FETs as described above.

The schematic flow chart diagrams that follow are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

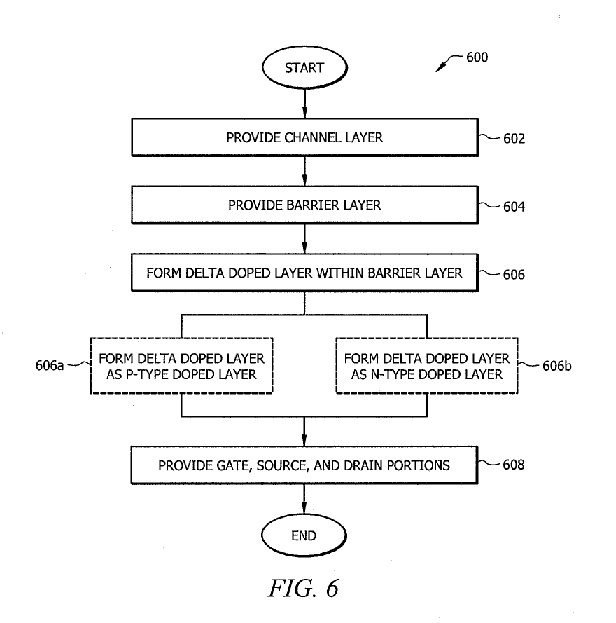

FIG. 6 illustrates one embodiment of a method 600 for fabricating a remote doped high performance transistor. In one embodiment, method 600 includes providing 602 a channel layer configured to convey charge from a source portion to a drain portion of the transistor when the transistor is in an active state. Additionally, method 600 includes providing 604 a barrier layer adjacent to the channel layer. Further, method 600 includes forming 606 a delta doped layer within the barrier layer, where the delta doped layer is configured to provide holes or electrons to the channel layer of the transistor.

In one example of method 600 described above, the delta doped layer may be formed as a p-type 606a or n-type 606b doped layer to provide either holes or electrons to the channel layer respectively, and may be designed to implement the functionality described above. Method 600 may also include providing 608 gate, source, and drain portions for the transistor where such providing 608 may include forming transistor as a multigate or MOSFET device.

All of the methods disclosed and claimed herein can be made and executed without undue experimentation in light of the present disclosure. While the apparatus and methods of this invention have been described in terms of preferred embodiments, it will be apparent to those of skill in the art that variations may be applied to the methods and in the steps or in the sequence of steps of the method described herein without departing from the concept, spirit and scope of the invention. In addition, modifications may be made to the disclosed apparatus and components may be eliminated or substituted for the components described herein where the same or similar results would be achieved. All such similar substitutes and modifications apparent to those skilled in the art are deemed to be within the spirit, scope, and concept of the invention as defined by the appended claims.

What is claimed is:

1. A Field-Effect Transistor (FET) comprising:
providing a channel layer configured to convey charge between a source portion and a drain portion of said FET when said FET is in an active state; and
a barrier layer adjacent to said channel layer, said barrier layer comprising a delta doped layer configured to provide carriers to said channel layer of said FET, while substantially retaining dopants in said delta-doped layer.

2. The FET of claim 1, wherein said delta doped layer is a p-type delta doped layer and is configured to provide holes to said channel layer.

3. The FET of claim 1, wherein said delta doped layer is an n-type delta doped layer and is configured to provide electrons to said channel layer.

4. The FET of claim 1, wherein said transistor is a multigate device.

5. The FET of claim 4, wherein said transistor is one of a group III-V or a group IV FinFET device and said barrier layer is placed between a hard mask and said channel layer.

6. The FET of claim 1, wherein said transistor is a one of a group III-V or group IV Metal-oxide Semiconductor Field-Effect Transistor (MOSFET) and said barrier layer is placed between a second barrier layer and said channel layer.

7. The FET of claim 1, wherein said delta doped layer is located approximately 2 nm away from the channel layer.

8. An Integrated Circuit (IC) device, comprising:
a chip package configured to house an IC;
a plurality of electrical interface pins coupled to the chip package and in communication with the IC, the electrical interface pins configured to conduct electrical signals; and
at least one Field-Effect Transistor (FET) disposed within the chip package, the FET comprising:
providing a channel layer configured to convey charge between a source portion and a drain portion of said FET when said FET is in an active state;
a barrier layer adjacent to said channel layer, said barrier layer comprising a delta doped layer configured to provide holes or electrons to said channel layer when said FET is in an active state, while substantially retaining dopants in said delta-doped layer.

9. The IC device of claim 8, wherein said delta doped layer is a p-type delta doped layer and is configured to provide holes to said channel layer.

10. The IC device of claim 8, wherein said delta doped layer is an n-type delta doped layer and is configured to provide electrons to said channel layer.

11. The IC device of claim 8, wherein said transistor is a multigate device.

12. The IC device of claim 11, wherein said transistor is one of a group III-V or a group IV FinFET device and said barrier layer is placed between a hard mask and said channel layer.

13. The IC device of claim 8, wherein said transistor is a one of a group III-V or group IV Metal-oxide Semiconductor Field-Effect Transistor (MOSFET) and said barrier layer is placed between a second barrier layer and said channel layer.

14. The IC device of claim 8, wherein said delta doped layer is located approximately 2 nm away from the channel layer.

15. The IC device of claim 8, wherein the said chip package further comprises at least one complimentary pair of transistors wherein the first transistor comprises a p-type delta doped layer and the second transistor comprises an n-type delta doped layer.

16. A method for fabricating a Field-Effect Transistor (FET), said method comprising:
providing a channel layer configured to convey charge between a source portion and a drain portion of said FET when said FET is in an active state;
providing a barrier layer adjacent to said channel layer; and
forming a delta doped layer within said barrier layer, said delta doped layer configured to provide holes or electrons to said channel layer of said FET.

17. The method of claim 16, wherein said forming said delta doped layer further comprises forming said delta doped layer as a p-type delta doped layer configured to provide holes to said channel layer.

18. The method of claim 16, wherein said forming said delta doped layer further comprises forming said delta doped layer as an n-type delta doped layer and is configured to provide electrons to said channel layer.

19. The method of claim 16, wherein said transistor is a multigate device.

20. The method of claim 19, wherein said transistor is one of a group III-V or a group IV FinFET device and said barrier layer is placed between a hard mask and said channel layer.

21. The method of claim 16, wherein said transistor is a one of a group III-V or group IV Metal-oxide Semiconductor Field-Effect Transistor (MOSFET) and said barrier layer is placed between a second barrier layer and said channel layer.

22. The method of claim 16, wherein said delta doped layer is located approximately 2 nm away from the channel layer.
